(19) United States
(12) Patent Application Publication
(10) Pub. No.: US 2024/0258372 A1
(43) Pub. Date: Aug. 1, 2024

(54) ELECTRONIC COMPONENT AND PACKAGE INCLUDING STRESS RELEASE STRUCTURE AS LATERAL EDGE PORTION OF SEMICONDUCTOR BODY

(71) Applicant: Infineon Technologies AG, Neubiberg (DE)

(72) Inventors: Sebastian POLSTER, Bad Abbach (DE); Alexander HEINRICH, Bad Abbach (DE); Martin Richard NIESSNER, München (DE)

(73) Assignee: Infineon Technologies AG, Neubiberg (DE)

(21) Appl. No.: 18/518,846

(22) Filed: Nov. 24, 2023

(30) Foreign Application Priority Data
Jan. 26, 2023 (DE) 10 2023 101 894.9

(51) Int. Cl. H01L 29/06; H01L 21/78; H01L 23/00

(52) U.S. Cl. CPC H01L 29/0657; H01L 21/78; H01L 24/29; H01L 24/32; H01L 24/83; H01L 29/1608; H01L 2224/29111; H01L 2224/29144; H01L 2224/3201; H01L 2224/32225; H01L 2224/32245; H01L 2224/8382; H01L 2924/10156; H01L 2924/10272

(57) ABSTRACT

An electronic component is disclosed. The electronic component comprises a semiconductor body, an active region in a central portion of the semiconductor body, and a stress release structure for releasing stress and being formed as a lateral edge portion of the semiconductor body. The lateral edge portion has a minimum thickness of not more than 40% of a maximum thickness of the semiconductor body.

### CROSS-REFERENCE TO RELATED APPLICATION

This Utility patent application claims priority to German Patent Application No. 10 2023 101 894.9 filed Jan. 26, 2023, which is incorporated herein by reference.

### BACKGROUND

### Technical Field

Various embodiments relate generally to an electronic component, a package, and a method of manufacturing an electronic component.

### Description of the Related Art

A conventional package may comprise for example an electronic component mounted on a chip carrier such as a leadframe, may be electrically connected by a bond wire extending from the chip to the chip carrier or to a lead, and may be molded using a mold compound as an encapsulant.

### SUMMARY

There may be a need for an electronic component with high reliability and reasonable manufacturing effort.

According to an exemplary embodiment, an electronic component is provided which comprises a semiconductor body, an active region in a central portion of the semiconductor body, and a stress release structure for releasing stress and being formed as a lateral edge portion of the semiconductor body, said lateral edge portion having a minimum thickness of not more than 40% of a maximum thickness of the semiconductor body.

According to another exemplary embodiment, a package is provided which comprises a carrier, and an electronic component having the above-mentioned features and being mounted on the carrier, wherein the stress release structure of the electronic component releases stress at an interface between the lateral edge portion and the carrier.

According to still another exemplary embodiment, a method of manufacturing an electronic component is provided, wherein the method comprises forming an active region in a central portion of a semiconductor body, and forming a stress release structure for releasing stress as a lateral edge portion of the semiconductor body, said lateral edge portion being formed with a minimum thickness of not more than 40% of a maximum thickness of the semiconductor body.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of an electronic component according to an exemplary embodiment.

FIG. 2 illustrates a flowchart of a method of manufacturing an electronic component according to an exemplary embodiment.

FIG. 3 illustrates a cross-sectional view of a package according to an exemplary embodiment.

FIG. 4 illustrates a plan view of a package according to an exemplary embodiment.

FIG. 5 illustrates a cross-sectional view of an electronic component according to an exemplary embodiment.

FIG. 6 illustrates a cross-sectional view of an electronic component according to an exemplary embodiment.

FIG. 7 illustrates a diagram plotting maximum tensile stress versus chamfer length.

FIG. 8 to FIG. 23 illustrate simulation results of simulating stress behaviour of electronic components to be surface mounted on a carrier according to exemplary embodiments.

FIG. 24 illustrates cross-sectional views during executing a method of manufacturing an electronic component according to an exemplary embodiment.

### DETAILED DESCRIPTION

There may be a need for an electronic component with high reliability and reasonable manufacturing effort.

According to an exemplary embodiment, an electronic component is provided which comprises a semiconductor body, an active region in a central portion of the semiconductor body, and a stress release structure for releasing stress and being formed as a lateral edge portion of the semiconductor body, said lateral edge portion having a minimum thickness of not more than 40% of a maximum thickness of the semiconductor body.

According to another exemplary embodiment, a package is provided which comprises a carrier, and an electronic component having the above-mentioned features and being mounted on the carrier, wherein the stress release structure of the electronic component releases stress at an interface between the lateral edge portion and the carrier.

According to still another exemplary embodiment, a method of manufacturing an electronic component is provided, wherein the method comprises forming an active region in a central portion of a semiconductor body, and forming a stress release structure for releasing stress as a lateral edge portion of the semiconductor body, said lateral edge portion being formed with a minimum thickness of not more than 40% of a maximum thickness of the semiconductor body.

According to an exemplary embodiment, an electronic component has a semiconductor body with a central active region (for instance having at least one monolithically integrated circuit element therein). A stress release structure may be provided which may be formed as a lateral edge portion of the semiconductor body for releasing stress during manufacture and/or use of the electronic component. Advantageously, said lateral edge portion may have a minimum thickness of not more than 40% of a maximum thickness of the semiconductor body. It has been found that when the thickness at the edge of the semiconductor body is locally reduced to 40% or less of the maximum thickness thereof, a highly efficient suppression of stress—in particular tensile stress—exerted to the semiconductor body may be achieved which may improve the reliability of the electronic component and a package in which such an electronic component is mounted on a carrier. To put it shortly, in particular when an electronic component is mounted on a carrier (such as a leadframe structure), a particular high amount of stress may be exerted to the edge of the semiconductor body at an interface to the carrier when a corresponding package is subjected to strongly varying temperatures. For instance, this may lead to a delamination of the electronic component from the carrier, for example in view of a CTE (coefficient of expansion) mismatch between the material of the electronic component and the material of the carrier. It has been found that a sufficiently strong local thinning at the edge of the semiconductor body may reduce stress and may enhance the mechanical reliability of the electronic component and the package. At the same time, locally thinning specifically a lateral edge portion of the semiconductor body for the purpose of releasing stress selectively in a mechanical weak point region of the electronic component may allow to keep other portions of the semiconductor body thicker. This may keep the electronic component as a whole stable and robust against mechanical impact and may guarantee compliance with applications requiring a certain thickness of a semiconductor body, for instance in an active region. For example, a chamfer may be formed in a lateral edge portion of a semiconductor body for creating a local thinning thereof in order to release stress specifically where most pronounced. Further advantageously, when locally thinning selectively or even only the lateral portion of the semiconductor body, a major portion of the semiconductor body may remain non-thinned and may thus be used for forming an active region without limitations. Focusing or limiting stress release thinning to a lateral edge portion of the semiconductor body may also allow to use semiconductor area efficiently in order to obtain a large number of electronic components per semiconductor wafer. Hence, exemplary embodiments may improve throughput, efficiency and yield.

### DESCRIPTION OF FURTHER EXEMPLARY EMBODIMENTS

In the following, further exemplary embodiments of the electronic component, the package and the method will be explained.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “semiconductor body” may in particular denote a body comprising a semiconductor material. The semiconductor body may be initially part of a semiconductor wafer and may be separated from the wafer compound during a manufacturing process. For example, the semiconductor body comprises silicon or silicon carbide. The semiconductor body may be predominantly made of a semiconductor material. For instance, the semiconductor body may be a plate-shaped structure or a cuboid-shaped structure.

In the context of the present application, the term “active region” may in particular denote a portion of a semiconductor body in which at least one integrated circuit element is formed or integrated. For instance, such an integrated circuit element may be monolithically integrated in the semiconductor body. For instance, such an integrated circuit element may be a diode, a transistor, an ohmic resistance, a capacitance or an inductance.

In the context of the present application, the term “stress release structure for releasing stress” may in particular denote a structural configuration of the semiconductor body which reduces, suppresses, dissipates or even eliminates stress exerted to the semiconductor body. More specifically, the stress release structure may be configured for releasing tensile stress. Additionally or alternatively, a stress release structure may also release other kinds of stress, for instance compressive stress. Furthermore, the stress release structure may specifically reduce stress in lateral edge portion of the semiconductor body. In such a lateral edge portion, a semiconductor body may be particularly prone to stress which may lead to delamination from a carrier in the lateral edge portion.

In the context of the present application, the term “lateral edge portion” may in particular denote a section of a semiconductor body directly next to at least part of a lateral outline of the semiconductor body. In particular, a lateral edge portion may correspond to at least part of a sidewall or even to the entire sidewall thereof. The lateral edge portion may extend from the lateral outline or sidewall laterally inwardly towards but not into the active region of the semiconductor body. For instance, the lateral portion may be an outer edge portion of the semiconductor body extending along at least part of a perimeter thereof.

In the context of the present application, the term “minimum thickness” may in particular denote the smallest vertical extension of the semiconductor body. In other words, the minimum thickness may be the vertical dimension of the lateral edge portion where being thinnest. For example, the thinnest section of the lateral edge portion may also be the thinnest section of the entire semiconductor body. For example, the minimum thickness may be larger than zero or may be zero. For instance, the minimum thickness may be present at the lateral outline of the semiconductor body.

In the context of the present application, the term “maximum thickness” may in particular denote the largest vertical extension of the semiconductor body. In other words, the maximum thickness may be the vertical dimension of the semiconductor body where being thickest. For example, the semiconductor body may have a constant thickness over its entire extension with the exception of the locally thinned lateral edge portion. For instance, the maximum thickness may be present in a central region inside of a lateral outline of the semiconductor body.

In the context of the present application, the term “package” may particularly denote an electronic device which may comprise one or more electronic components mounted on a (in particular at least partially electrically conductive) carrier. Said constituents of the package may be optionally encapsulated at least partially by an encapsulant. Further optionally, one or more electrically conductive interconnect bodies (such as metallic pillars, bumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad.

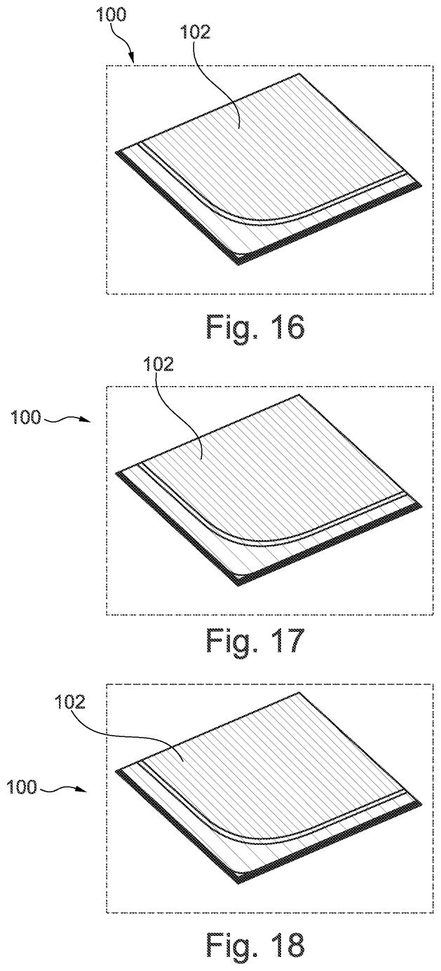

In an embodiment, a lateral extension of the stress release structure between an exterior edge of the semiconductor body and a position at which the semiconductor body reaches its maximum thickness is at least 10% of the maximum thickness of the semiconductor body. A sufficiently large lateral extension of the stress release structure has a positive impact on the suppression of tensile stress, see for example FIG. 7. Hence, it may be advantageous that the lateral extension of the stress release structure is at least one tenth of the maximum semiconductor thickness.

In an embodiment, said lateral extension of the stress release structure is at least 20% of the maximum thickness of the semiconductor body. Again referring to FIG. 7, the tensile stress may be further reduced when the lateral extension of the release structure is further increased, preferably up to or above 20%. Descriptively speaking, this may extend the spatial range of the semiconductor body in which it is actively protected against stress.

In an embodiment, said lateral extension of the stress release structure is not more than 150 μm, in particular not more than 100 μm. As can be taken from FIG. 7 as well, the positive impact of a sufficiently large lateral extension of the stress release structure becomes weaker when certain limits are exceeded. Hence, a further increase of the lateral extension of the stress release structure may then have an only smaller impact on the further improvement of the stress relief. At the same time, it may be advantageous to limit the lateral extension of the stress release structure, preferably with an upper limit of 150 μm, to keep the active usable semiconductor area of the semiconductor body large. This may allow to manufacture a high number of semiconductor chip-type electronic components per wafer. To put it shortly, the percentage of the active area of a semiconductor body divided by the entire area thereof may then be increased.

In an embodiment, said lateral edge portion has a minimum thickness of not more than 20% of the maximum thickness of the semiconductor body. A further intensified thinning of the lateral edge portion to one fifth or less of the maximum value may further enhance stress release at the most critical edge region of the semiconductor body.

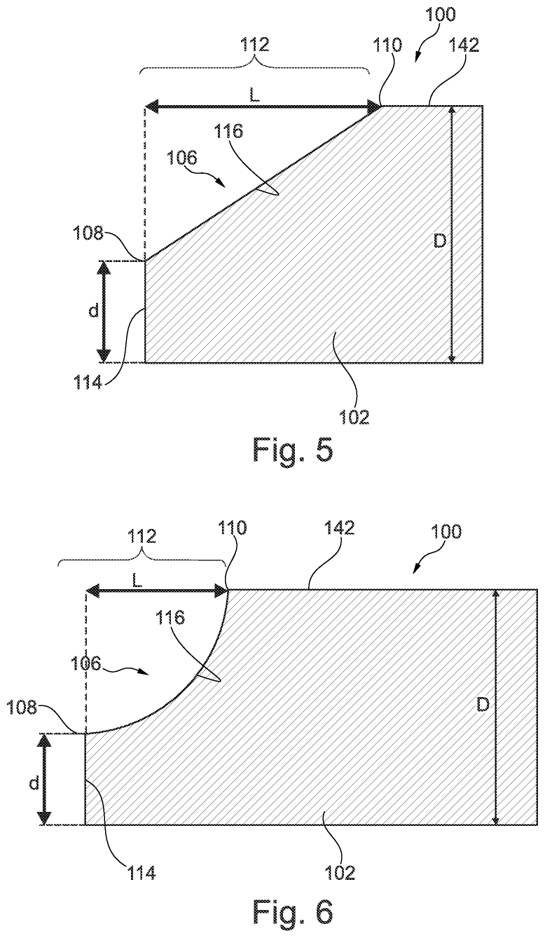

In an embodiment, said lateral edge portion has a minimum thickness of zero at an exterior edge of the semiconductor body. As shown for instance in FIG. 3, the edge thickness may even be reduced to zero at the exterior end, which may avoid any vertical sidewall. This may provide an excellent protection against stress. For instance, the thickness of the semiconductor body may be gradually, preferably linearly, reduced to zero for creating a package being reliably protected against delamination between electronic component and carrier.

In an embodiment, at least part of the lateral edge portion has a concave shape or has a straight shape. A concave shape has the advantage that a very large thickness reduction may be achieved over a small lateral extension. Hence, an efficient stress release may be combined with a very low loss of semiconductor area for forming an active region. When the lateral edge portion is formed with a straight shape, an efficient stress release may be obtained while creating a mechanically robust edge portion.

In an embodiment, the maximum thickness is in a range from 20 μm to 220 μm, in particular in a range from 30 μm to 120 μm. For example, the maximum thickness may be 110 μm. As can be taken from the mentioned ranges, even designs may be satisfied which require a relatively large thickness without compromising on stress-caused delamination.

In an embodiment, the minimum thickness at the lateral edge portion is not more than 50 μm, in particular not more than 30 μm, more particularly in a range from 10 μm to 30 μm. Such a minimum thickness at the outermost end of the thinned lateral edge portion may be sufficiently small for efficiently dissipating stress where it is most pronounced over the extension of the semiconductor body, i.e. in the edge regions.

In an embodiment, the stress release structure extends along an entire circumference of the semiconductor body. When the stress release structure is formed as a closed annular structure (for instance chamfer) extending along the whole perimeter of the semiconductor body, no stress peaks will occur along the perimeter and a particularly reliable package may be manufactured.

In an alternative embodiment, the stress release structure may extend only in one or more limited perimeter sections around the circumference of the semiconductor body. This may allow to obtain a very high semiconductor area for forming active devices.

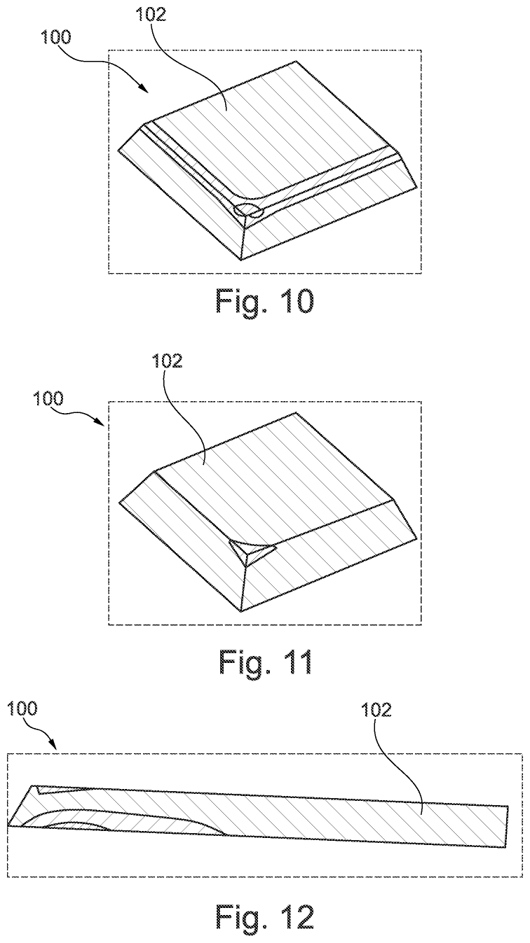

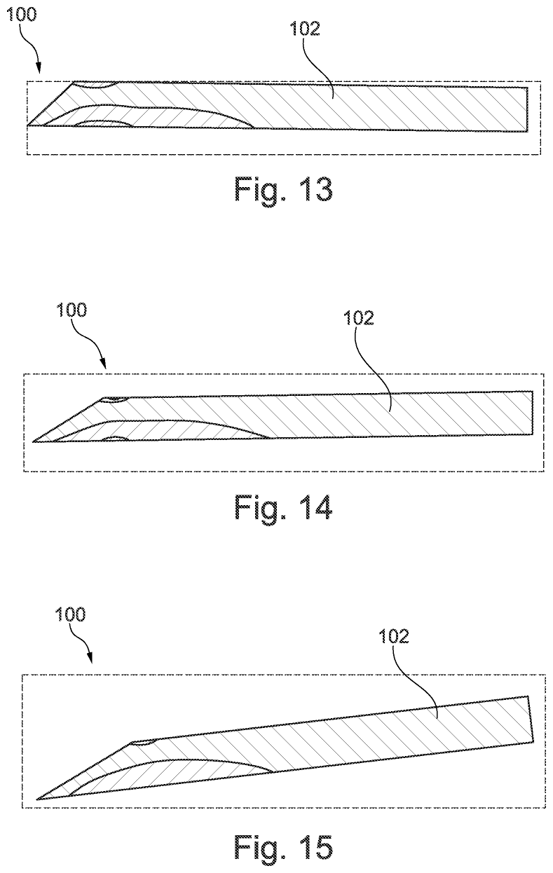

In an embodiment, the stress release structure is delimited by a vertical section at an exterior edge of the semiconductor body and by a slanted section connected between said vertical section and a horizontal surface of the semiconductor body. For example, the slanted section may be straight (see FIG. 5) or may be concave (see FIG. 6). In particular a concave structure may be easily formed by a combination of mechanically dicing with laser dicing or by a two-stage mechanical dicing process. Furthermore, a concave recess or indentation may lead to a strong thickness reduction over a small lateral dimension thereby ensuring both an efficient stress release and an efficient use of the semiconductor area.

In an embodiment, the stress release structure is configured for releasing tensile stress. Tensile stress may be stress which stretches the semiconductor body in a particular direction. However, it may be possible, additionally or alternatively, that a stress release structure is configured for releasing compressive stress. Compressive stress can be defined in the same way as tensile stress but it has negative values so as to express a compression of the semiconductor body. The stress released by the stress release structure may be thermally-caused, i.e. may be caused by heating and/or cooling.

In an embodiment, the electronic component is configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning stress relief are particularly pronounced for power dies.

In an embodiment, the package is configured as power package. A power package may be a package comprising at least one power chip as electronic component. Thus, the package may be configured as power module, for instance molded power module such as a semiconductor power package. For instance, an exemplary embodiment of the package may be an intelligent power module (IPM). Another exemplary embodiment of the package is a dual inline package (DIP).

In an embodiment, the semiconductor body comprises silicon carbide. Since silicon carbide has a significantly larger stiffness than for example silicon or other semiconductor materials, the risk of damage of a package in particular in an interface region between a carrier and the electronic component may be particularly pronounced for silicon carbide-type electronic components. Specifically in silicon carbide technology, stress release may be of utmost advantage.

In an embodiment, the stress release structure is formed as a stress release notch or as a stress release chamfer at the lateral edge portion of the semiconductor body. Such a notch or a chamfer may preferably be concave shaped for achieving a pronounced reduction of the semiconductor thickness over a short lateral dimension.

In an embodiment, the carrier comprises a metallic material at the interface with the electronic component. Hence, the metallic carrier material may face the semiconductor material of the electronic component, for instance separated only by a thin layer of solder. This may lead to an abrupt change of the coefficient of thermal expansion at the interface. Consequently, temperature changes may cause stress at the interface, tending to delaminate the electronic component from the carrier. By the stress release structure, such a tendency may be strongly suppressed.

In an embodiment, the carrier comprises one of the group consisting of a leadframe structure, and a ceramic sheet with metallic layers on both opposing main surfaces thereof. For example, the carrier is a leadframe structure (for instance made of copper). Preferably, such a leadframe-type carrier comprises a die paddle or die pad, on which the electronic component is mounted. Furthermore, such a leadframe-type carrier may comprise at least one lead, preferably a plurality of leads. A leadframe structure may be a metal structure of the package that carries signals from the electronic component to the outside, and/or in opposite direction. It is however also possible that such a carrier is a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by an encapsulant, together with the electronic component.

In an embodiment, the package comprises a solder layer between the carrier and the electronic component. For example, the solder layer has a thickness of less than 10 μm, in particular a thickness in a range from 1 μm to 5 μm. Correspondingly, the manufacturing method may comprise mounting the electronic component on a carrier by soldering, in particular by diffusion soldering. Such a thin layer of solder may be used to connect the electronic component with the carrier by diffusion soldering. During diffusion soldering, the electronic component may be pressed onto the carrier at an elevated temperature of in particular above 200° C. This may cause a solid connection between electronic component and carrier, followed by a cooling down to room temperature. Generated thermal stress, which may conventionally cause artifacts between electronic component and carrier, may be significantly reduced by the stress release structure in the edge portion of the electronic component.

In an embodiment, the method comprises separating the semiconductor body from a wafer along separation lines so that the stress release structure is formed by said separating. Advantageously, singulating a semiconductor wafer into electronic components (in form of semiconductor chips) may be synergistically combined with the formation of a stress release structure for releasing stress at the semiconductor body or between the semiconductor body and a carrier. This may render the manufacturing process highly efficient. For example, process parameters (for instance laser cutting power) and/or hardware parameters (for instance the shape of a mechanical cutting blade) may be selected for adjusting the shape of the stress release structure at the lateral edge portion of the semiconductor body.

In an embodiment, said separating comprises carrying out a first separation process penetrating into (but not entirely through) the wafer, and carrying out a subsequent second separation process penetrating through the wafer (i.e. finally separating it into separate semiconductor bodies or electronic components). By two-stage dicing, a first dicing stage extending only through part of the wafer may define a shape of the stress release structure at the lateral edge portion of the semiconductor body, before the second dicing stage may complete dicing by extending through the entire wafer also completing shape definition of the stress release structure. This may allow to simply and precisely define the characteristics of the stress release structure. For example, the first dicing stage may form a broader and the second dicing stage may form a deeper dicing trench.

In an embodiment, one or both of the first separation process and the second separation process comprises a mechanical dicing process. For example, a first separation process may be a first mechanical dicing process using a broader dicing blade than a subsequent second mechanical dicing process using a narrower dicing blade.

In an embodiment, the second separation process comprises a laser dicing process. For example, a first separation process may be a mechanical dicing process using a dicing blade, whereas a second separation process may be a laser dicing process forming a narrower cut than the mechanical dicing process. A laser dicing process may be a dry laser dicing process during which a laser beam cuts at least part of the thickness of a semiconductor wafer. An example of a dry laser cutting process appropriate for defining a stress release structure is a multibeam laser dicing process. However, a laser dicing process may also be a wet laser dicing process during which a laser beam is guided in a liquid (such as water) when cutting through at least part of the thickness of a semiconductor wafer. Advantages of a wet laser cutting process are a proper spatial guiding and cooling of the laser beam. Furthermore, a wet laser cutting process may reduce burn-off.

In an embodiment, said separating comprises carrying out a single separation process penetrating through the wafer by a laser, in particular by a multi-beam laser or by a liquid-guided laser. Hence, only a single dicing process may be sufficient for simultaneously separating individual semiconductor bodies or electronic components and forming stress release structures with well-defined shape.

In an embodiment, it is possible that said separating comprises only a single laser dicing stage. For instance when using a multibeam laser, it may be possible to form a chamfered lateral edge portion with stress release function by a single laser cut.

In an embodiment, the method comprises forming the stress release structure by etching. In particular, an anisotropic etching process may be used for removing semiconductor material for defining a shape of the stress release structure, for instance in form of a chamfered lateral edge portion thereof. Said etching may or may not contribute to the separation of a wafer into individual semiconductor bodies or electronic components. It is also possible that separation of a wafer into individual electronic components is firstly completed (for instance mechanically and/or by a laser), and subsequently the separated electronic components are subjected to an etching treatment for defining or refining the geometry of the stress release structure at the lateral edge portion of the semiconductor body.

In an embodiment, the package comprises an encapsulant encapsulating at least part of the electronic component. In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In an embodiment, the package comprises at least one electrically conductive coupling element electrically coupling the electronic component with the carrier (in particular with a die pad and/or with at least one lead). Such an electrically conductive coupling element may be a clip, a bond wire or a bond ribbon. A clip may be a curved electrically conductive body accomplishing an electric connection with a high connection area to an upper main surface of a respective electronic component. Additionally or alternatively to such a clip, it is also possible to implement one or more other electrically conductive interconnect bodies in the package, for instance a bond wire and/or a bond ribbon connecting the electronic component with the die pad and/or a lead or connecting different pads of an electronic component.

For example, a package according to other exemplary embodiments may be configured as one of the group consisting of a leadframe connected power module, a Control integrated power system (CIPOS) package, a Transistor Outline (TO) package, a Quad Flat No Leads Package (QFN) package, a Small Outline (SO) package, a Small Outline Transistor (SOT) package, and a Thin Small Outline Package (TSOP) package. For example, the package may be implemented in a “CIPOS™ Mini” configuration or a “TO-247” configuration of the applicant Infineon Technologies AG. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts and appears externally as a conventional package, which is highly user convenient.

In an embodiment, at least one further electronic component in mounted on the carrier. Thus, a plurality of electronic components may be mounted side by side on the same carrier. For instance, at least two electronic components may be mounted on one carrier. This may allow to realize even complex or sophisticated electronic functionality while achieving a low stress package.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

In order to increase the current output of packages such as silicon carbide based devices, their operating temperature may be increased. However, increasing the operating temperature may lead to a lifetime reduction of the package. Hence, the specification for passive temperature cycles cannot be met anymore in some cases, as delamination may occur at the interface between chip and leadframe. Delamination usually starts at the corners or edges of the chips.

One way to overcome the stress at this interface is to reduce the entire chip thickness. This option, however, may be limited due to design rules of the devices.

According to an exemplary embodiment, a package is provided comprising an electronic component mounted on a carrier. A semiconductor body of the electronic component may comprise a central active region with at least one integrated circuit element surrounded by a lateral edge portion apart from the active region. Advantageously, a stress release structure is formed in said lateral edge portion by locally thinning it to a minimum thickness of not more than 40% of a maximum thickness of the semiconductor body. It has been found that stress, in particular tensile stress, predominantly acts in a lateral portion of a semiconductor body of an electronic component. Such stress may be exerted in particular in the event of extreme temperatures or significant temperature changes, as may occur during a package manufacturing process (for instance during soldering an electronic component on a carrier) and/or during operation of the package under harsh thermal conditions. In particular, this may cause delamination of the electronic component from the carrier specifically in a lateral edge portion (for instance in corners and/or along edges). It has furthermore been found that a local thinning in the lateral edge portion may significantly reduce stress where the electronic component is most prone to failure, in particular when mounted on a carrier made of another material than the electronic component so that a CTE mismatch may be present at an interface. To put it shortly, a local thinning in form of a chip chamfer may be formed at a lateral edge portion of the semiconductor body for stress release where stress is most pronounced over the extension of the semiconductor body. Such a local thinning of a lateral edge portion up to 40% or less of the maximum semiconductor body thickness may locally release stress and may therefore avoid reliability issues such as delamination or warpage. A sufficiently strong local thinning of a lateral edge portion of a semiconductor body while maintaining a higher thickness in a central portion of the semiconductor body comprising the active region thereof may allow to achieve stress relief where the electronic component is most prone to failure due to delamination from a carrier. Simultaneously, design rules of the electronic component or package which may require a sufficiently large thickness in the active region may be complied with.

Hence, instead of reducing the thickness of the whole chip, an exemplary embodiment selectively reduces the chip thickness only at the position(s) of the highest stress, which may be the chip edges, where delamination starts. In an embodiment, a thickness reduction at the chip edges can be realized as a chamfer. Such a chamfer can be created, for example, by correspondingly designing dicing blades during the dicing process of a semiconductor wafer.

More specifically, an exemplary embodiment provides an electronic component with a stress releasing structure at the edges. Preferably but not necessarily, such an electronic component may be embodied as silicon carbide (SiC) chip. A semiconductor body of silicon carbide may have a very high value of the Young modulus and may thus be very stiff. Hence, a silicon carbide semiconductor body may be specifically prone to thermally caused tensile stress. In order to prevent delamination of such a silicon carbide chip from the carrier (for instance a leadframe), a local stress reduction in the lateral edge portion may be highly efficient.

For example, such a stress release structure or stress relieving structure can be formed during a dicing process during which an electronic component is singulated from a wafer compound. A resulting stress release structure may be a straight chamfer at the chip edge(s). Alternatively, the stress release structure can be etched, for example on wafer level. Simulations show that a chamfer locally reducing the semiconductor body thickness to 40% or less may result in a pronounced reduction of the stress level, in particular what concerns tensile stress. It has also be found during simulations that a stress release structure's extension of 50 μm or more towards a semiconductor body center already leads to a highly significant stress reduction.

According to an exemplary embodiment, a method to release stress from chip edges by chamfering chip edges is provided. In this context, a chamfering or beveling or concave rounding of edges of a semiconductor body of an electronic component (in particular a silicon carbide chip) can be carried out. Such a processed lateral edge portion of a semiconductor may act as stress reliever. In particular, such a stress relieving chamfer may be configured to prevent delamination of the semiconductor chip-type electronic component from a carrier (such as a copper leadframe). Such a carrier may be provided with a thin film of solder (for instance comprising tin or a tin alloy, such as AuSn) as die-attach material.

Preferably, the stress relieving chamfer is created during a dicing process by which individual electronic components are separated from a wafer compound. For example by laser dicing, mechanical dicing (preferably employing blades shaped for forming a lateral edge portion) or a combination of both, a stress releasing lateral edge structure may be formed. It is also possible to carry out a two-stage dicing process (or a dicing process comprising three or more stages) for forming a stress release structure as lateral edge portion of the semiconductor body. Alternatively, it may be possible to form the stress release structure as lateral edge portion by etching on wafer level.

In an embodiment, a straight chamfer or a rounded cavetto edge chamfering can be created. For example, a chamfer length or a radius of curvature may be at least 50 μm.

An advantage of chamfering for forming a stress release structure as lateral edge portion of the semiconductor body is that an improved reliability of a corresponding package may be achieved, in particular what concerns an interface between a carrier and an electronic component mounted thereon. In particular, exemplary embodiments may have the advantage that a silicon carbide based device (having an extraordinarily high stiffness) can operate at a very high temperature and electric current. A stress release structure may improve the reliability during a soldering process (in particular during diffusion soldering), during which high temperatures of for example more than 200° C. may occur. Corresponding thermal stress may be prevented from causing delamination and other issues with an electronic component of a package thanks to the stress release structure. Hence, conventional shortcomings such as lifetime reduction, delamination, etc., may be reliably prevented by forming a chamfer on chip edges for releasing stress.

In particular for extraordinarily stiff silicon carbide-type electronic components, a stress release chamfer which locally thins a semiconductor body in a lateral edge portion up to 40% or less may improve package reliability significantly. Hence, exemplary embodiments may be applied particularly advantageously for silicon carbide electronic components. In particular, it may be advantageously possible to increase the operation temperature of silicon carbide-type devices by an appropriate side wall design of its semiconductor body.

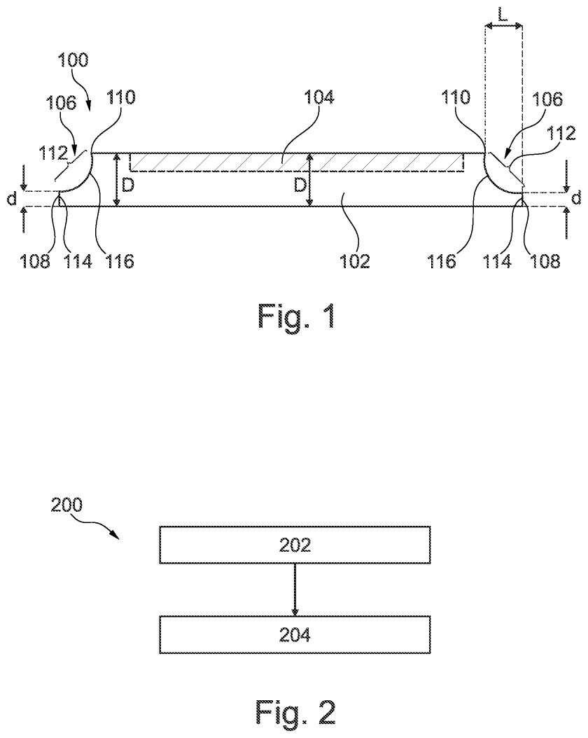

FIG. 1 illustrates a cross-sectional view of an electronic component 100 according to an exemplary embodiment. In particular, electronic component 100 may be configured as a power semiconductor chip. The illustrated electronic component 100 may be a bare die.

The illustrated electronic component 100 comprises a semiconductor body 102. For example, the semiconductor body 102 may be a silicon body or a silicon carbide body. An active region 104, for instance formed in a surface portion of the semiconductor body 102, is arranged in a central portion of the semiconductor body 102. For example, the active region 104 comprises at least one integrated circuit element being monolithically integrated in the semiconductor body 102. For instance, such at least one integrated circuit element may be a transistor (such as a field effect transistor, for instance a metal oxide semiconductor field effect transistor, MOSFET), a diode, an inductance and/or a capacitance.

Furthermore, the semiconductor body 102 comprises a stress release structure 106 for releasing stress exerted to the electronic component 100. Said stress release structure 106 may be formed by a slanted section 116 at a lateral edge portion 112 of the semiconductor body 102. As shown, the stress release structure 106 is formed as a stress release notch or chamfer at the lateral edge portion 112 of the semiconductor body 102. More specifically, said lateral edge portion 112 may have a minimum thickness d of not more than 40%, preferably not more than 20%, of a maximum thickness D of the semiconductor body 102. In the central portion of the semiconductor body 102, a constant thickness corresponding to said maximum thickness D is present. For example, the maximum thickness D may be in a range from 30 μm to 120 μm, for instance 110 μm. Correspondingly, the minimum thickness d at the lateral edge portion 112 may be preferably in a range from 10 μm to 30 μm, for instance 20 μm. Such a configuration may reduce thermally caused stress, in particular tensile stress, exerted to the lateral edge portion 112. Since the lateral edge portion 112 of the semiconductor body 102 may be the mechanical weak point of the electronic component 100, forming the chamfered lateral edge portion 112 may lead to significantly reduced stress specifically where critical. In particular, this may reliably avoid an undesired delamination of the electronic component 102 from a carrier (see reference sign 122 in FIG. 3) when the electronic component 102 forms part of a package (see reference sign 120 in FIG. 3). The maximum thickness D of the semiconductor body 102 may be present in its entire central portion where the active region 104 is located. It is also possible that the maximum thickness D of the semiconductor body 102 is present everywhere apart from the lateral edge portion 112. The lateral edge portion 112 may extend in an annular way around the entire perimeter of the semiconductor body 102.

Furthermore, it may be advantageous that a lateral extension L of the stress release structure 106 between an exterior edge 108 of the semiconductor body 102 and a position 110 at which the semiconductor body 102 reaches its maximum thickness D is at least 10%, preferably at least 20%, of the maximum thickness D of the semiconductor body 102. This design rule may also have a positive impact on the reliability of the electronic component 100 and the corresponding package 120. At the same time, it may be advantageous that said lateral extension L of the stress release structure 106 is not more than 150 μm, preferably not more than 100 μm. This may ensure that a major portion of the semiconductor body 102 may be used for forming an active region 104, and that the non-used edges remain as small as possible without compromising on stress relief.

In the shown embodiment, the lateral edge portion 112 has a concave shape and is configured as a chamfer. Although not visible in FIG. 1, the stress release structure 106 may extend along an entire circumference of the semiconductor body 102, i.e. as closed annular structure. This may create a stress release protection along the entire perimeter.

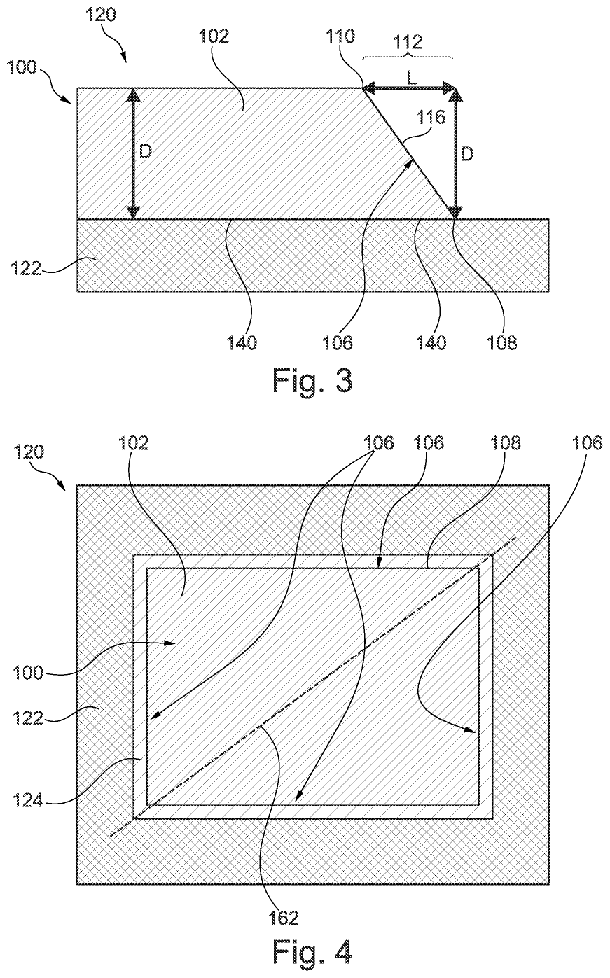

FIG. 2 illustrates a flowchart 200 of a method of manufacturing an electronic component 100 according to an exemplary embodiment. The reference signs used for the following description of said manufacturing method relate to the embodiment of FIG. 1.

Referring to a block 202, the method comprises forming an active region 104 in a central portion of a semiconductor body 102.

Referring to a block 204, the method comprises forming a stress release structure 106 for releasing stress as a lateral edge portion 112 of the semiconductor body 102, said lateral edge portion 112 being formed with a minimum thickness d of not more than 40% of a maximum thickness D of the semiconductor body 102.

FIG. 3 illustrates a cross-sectional view of a package 120 according to an exemplary embodiment.

The illustrated package 120 comprises a carrier 122. Carrier 122 may be plate-shaped and may be made of a metallic material, such as copper. For example, carrier 102 may be embodied as a patterned metal plate, such as a leadframe structure.

As shown, an electronic component 100 is mounted on the carrier 122. This may be accomplished, for example, by soldering, sintering or by dielectric or electrically conductive glue. The electronic component 100 according to FIG. 3 is shown only partially. Also in FIG. 3, the electronic component 102 may be a semiconductor chip, for instance manufactured in silicon carbide technology or silicon technology. As in FIG. 1, a stress release structure 106 of the electronic component 102 is provided and is configured for releasing stress in particular at its lateral edge portion 112. More specifically, said stress release structure 106 is formed as a lateral edge portion 112 of the semiconductor body 102. In contrast to FIG. 1, the lateral edge portion 112 of the electronic component 102 according to FIG. 3 has a minimum thickness d of zero. In other words, the lateral edge portion 112 may be continuously thinned towards its exterior edge 108 with thickness zero. Thus, said lateral edge portion 112 has a minimum thickness d of zero at the exterior edge 108 of the semiconductor body 102. The reduction of the minimum thickness d up to zero may avoid any vertical flank or sidewall which may have a positive impact on stress reduction. According to FIG. 3, the lateral edge portion 112 has a straight shape rather than being concave.

In the package 120 according to FIG. 3, the stress release structure 106 of the electronic component 100 releases stress at an interface 140 between the electronic component 100 and the carrier 122, and more specifically in the lateral edge portion 112. As already mentioned, the carrier 122 comprises a metallic material at the interface 140 with the electronic component 100. Consequently, in the region of the interface 140, there is a relatively abrupt transition from semiconductor material (for instance silicon carbide) to a metallic material (for example copper). Since the mentioned materials have very different coefficients of thermal expansion (CTE), a considerable CTE mismatch may occur at interface 140. When assembling semiconductor-type electronic component 100 on metallic carrier 122, this CTE mismatch may lead to stress, in particular tensile stress, in the region of interface 140. Said stress may be particularly pronounced in the region of the lateral edge portion 112. By locally thinning the semiconductor body 102 selectively or exclusively in the lateral edge portion 112, said stress may be released or reduced significantly. As a result, temperature changes (which may occur during die assembly, for instance soldering, and/or during operation of the package 120 under harsh thermal conditions) leading to thermal stress may be prevented from having a negative impact on the package 120 by the stress release structure 106. By reducing stress in particular at the weak point of the package 120, i.e. in the lateral edge portion 112, thanks to the stress release structure 106, undesired phenomena such as delamination at interface 140 in the lateral edge portion 112 may be suppressed or even eliminated. This may improve reliability of the package 120.

For example, thickness D of the entire semiconductor body 102 apart from the lateral edge portion 112 may be 110 μm. Along a lateral extension L of the lateral edge portion 112, the thickness of the lateral edge portion 112 may be continuously and linearly reduced up to zero at the exterior edge 108 of the semiconductor body 102 by the illustrated design of the lateral edge portion 112. For instance, said lateral extension L may be in a range from 10 μm to 250 μm, preferably not more than 150 μm. By correspondingly limiting the lateral extension L of the lateral edge portion 112, it may be ensured that the vast majority of the semiconductor area may be used for creating an active region 104 (not shown in FIG. 3). This may lead to an efficient use of this semiconductor area and therefore a high efficiency, throughput and yield.

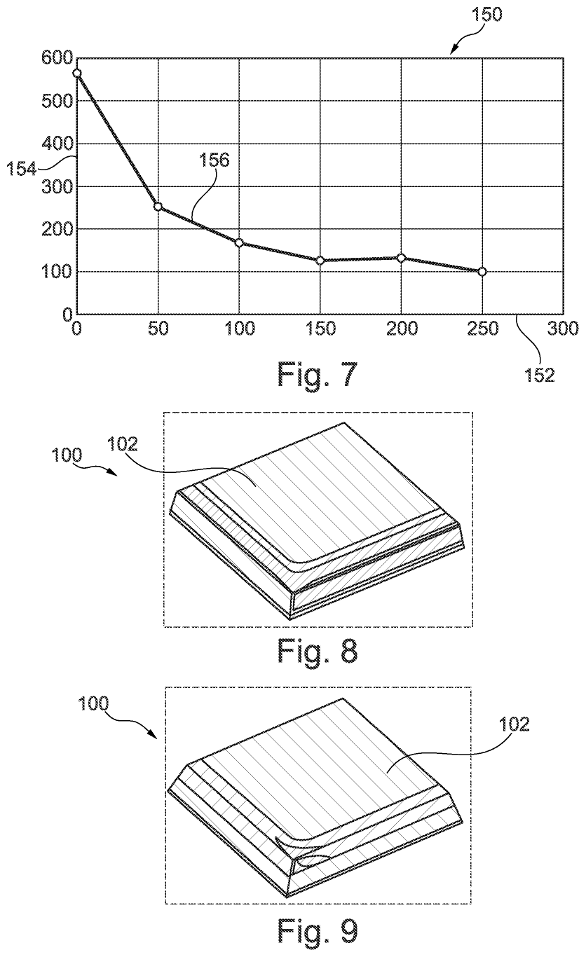

FIG. 4 illustrates a plan view of a package 120 according to an exemplary embodiment.

For example, the lateral edge portion 112 of the semiconductor body 102 according to FIG. 4 may be configured as described above referring to FIG. 1 or FIG. 3 or described below according to FIG. 5 or FIG. 6.

As can be taken from the plan view of FIG. 4, package 120 comprises a thin film-type solder layer 124 between the carrier 122 and the electronic component 100. In other words, assembly of the electronic component 100 (for instance a stiff semiconductor chip manufactured in silicon carbide technology) on carrier 122 (for example a Direct Copper Bonding (DCB) substrate having a ceramic sheet covered on both opposing main surfaces thereof by a respective copper layer) may be accomplished by soldering. For example, the solder layer 124 has a very small vertical thickness, for example in a range from 1 μm to 5 μm. During diffusion soldering, a bond line thickness of for instance 2 μm may be created. For example, the solder layer 124 may be a thin layer of AuSn alloy. When the electronic component 100 is mounted on the carrier 122 by diffusion soldering, the electronic component 100 may be pressed onto the carrier 122 (which may exert compressive stress) at elevated temperature for achieving a reliable connection. However, this will lead to a hard coupling due to the significant stiffness of the semiconductor material of the electronic component 100. Due to the pronounced CTE mismatch between the semiconductor and the metallic material at interface 140, thermal stress may be caused during heating and cooling during and after soldering. Hence, a high tension may occur during creating the solder connection between electronic component 100 and carrier 122. Establishing the solder connection between the electronic component 100 and the carrier 122 may involve a heating of the solder layer 124 to a very high temperature in a range from 230° C. to 410° C. Diffusion soldering, i.e. attaching the chip-type electronic component 100 to the carrier 122, may have very high temperatures up to 410° C. Consequently, a high amount of thermal stress may be exerted to the carrier 122 and the electronic component 100 during soldering, in particular around interface 140 in between. This may be in particular due to the pronounced CTE mismatch in between. However, the stress release structure 106 may significantly reduce said thermal stress, as explained above.

As shown in FIG. 4, the stress release structure 106 may extend along an entire circumference of the semiconductor body 102, i.e. may be a circumferentially closed structure.

FIG. 5 illustrates a cross-sectional view of an electronic component 100 according to an exemplary embodiment.

According to FIG. 5, the stress release structure 106 is delimited by a vertical section 114 at an exterior edge 108 of the semiconductor body 102 and by a slanted section 116 connected between said vertical section 114 and a horizontal surface 142 of the semiconductor body 102. In the embodiment of FIG. 5, the slanted section 116 is straight. Hence, the horizontal surface 142 of the semiconductor body 102 (also encompassing the active region 104 which is not visible in FIG. 5) transits at a position 110 into straight slanted section 116 (having a lateral extension corresponding to dimension L) which transits, in turn, at the lateral edge 108 into the vertical section 114 having a height corresponding to dimension d. When the height according to dimension d is not more than 40% of the maximum thickness D which the semiconductor body 102 has at horizontal surface 142, a sufficient thinning in the lateral edge portion 112 is obtained for significantly releasing thermally-caused stress.

FIG. 6 illustrates a cross-sectional view of an electronic component 100 according to an exemplary embodiment.

The embodiment of FIG. 6 differs from the embodiment according to FIG. 5 in that, according to FIG. 6, slanted section 116 is concave rather than straight. With a concave exterior surface of the semiconductor body 102 in the lateral edge portion 112, a significant reduction of the semiconductor thickness from the maximum value D to the minimum value d may be achieved over a short spatial extension in horizontal direction. As a result, the lateral extension L, which cannot be used for forming an active region 104, may be strongly reduced, so that the semiconductor area can be used very efficiently according to FIG. 6.

FIG. 7 illustrates a diagram 150 plotting maximum tensile stress versus chamfer length. More specifically, diagram 150 comprises an abscissa 152 along which a chamfer length is plotted in micrometers. A reference length of zero at abscissa 152 corresponds to a design in which a ratio between a lateral extension L of a chamfer and a maximum thickness D of the semiconductor body is less than 10%. More specifically, the reference length of zero denotes a configuration of L=10 μm for a chip thickness D=110 μm, i.e. L/D=10 μm/110 μm being less than 10%. Furthermore, diagram 150 comprises an ordinate 154 along which maximum tensile stress is plotted in MPa. Diagram 150 corresponds to an electronic component having a maximum thickness D of 110 μm. Hence, FIG. 7 illustrates the impact of chamfer length on maximum tensile stress. As can be taken from FIG. 7, a huge improvement may be achieved up to 50 μm on abscissa 152, and a further improvement may be obtained up to a value of 150 μm on abscissa 152. A further increase of the chamfer length does not lead to a significant further improvement. Hence, FIG. 7 shows that a stress release structure 100 limited over a certain lateral extension L may allow to significantly reduce tensile stress while simultaneously using chip area efficiently.

As can be taken from curve 156 of the diagram 150, the maximum tensile stress may be significantly reduced when increasing the chamfer length.

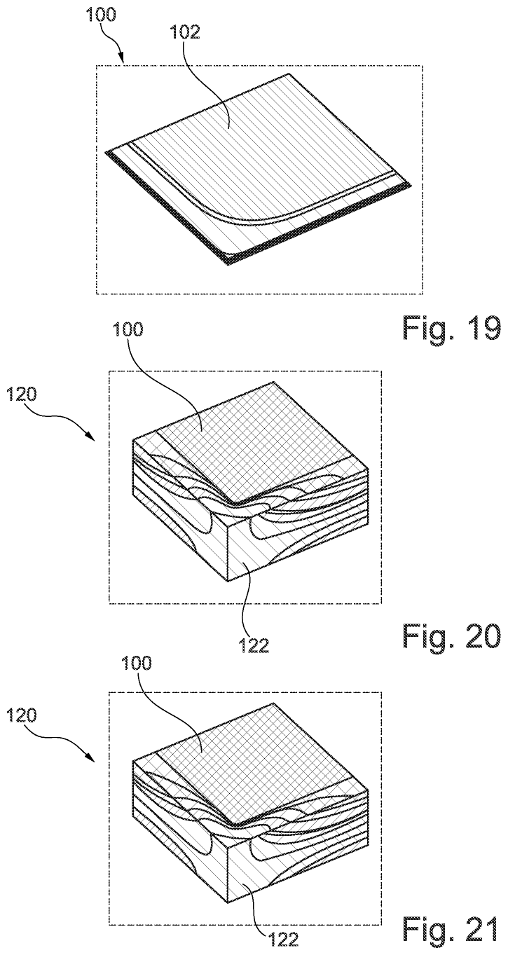

FIG. 8 to FIG. 23 illustrate simulation results of simulating stress behaviour of electronic components 100 to be surface mounted on a carrier 122 according to exemplary embodiments.

FIG. 8 to FIG. 11 shows simulation results of first principle stress and illustrate three-dimensional views of electronic components 100 with semiconductor body 102.

Referring to FIG. 8, simulation results for an electronic component according to an exemplary embodiment are shown which correspond to a chamfer with a lateral extension of 50 μm.

Referring to FIG. 9, simulation results for an electronic component according to an exemplary embodiment are shown which correspond to a chamfer with a lateral extension of 100 μm.

Referring to FIG. 10, simulation results for an electronic component according to an exemplary embodiment are shown which correspond to a chamfer with a lateral extension of 150 μm.

Referring to FIG. 11, simulation results for an electronic component according to an exemplary embodiment are shown which corresponds to a chamfer with a lateral extension of 200 μm.

Hence, FIG. 8 to FIG. 11 show that an acceptably small stress may be obtained in a lateral edge portion of the semiconductor body by providing a stress release structure of sufficient lateral extension.

FIG. 12 to FIG. 15 shows corresponding simulation results for a diagonal cut (see reference sign 162 in FIG. 4. FIG. 12 corresponds to FIG. 8, FIG. 13 corresponds to FIG. 9, FIG. 14 corresponds to FIG. 10, and FIG. 15 corresponds to FIG. 11. The findings described referring to FIG. 7 to FIG. 11 are confirmed by the findings according to FIG. 12 to FIG. 15.

FIG. 16 to FIG. 19 shows simulation results of von-Mises stress by die attach and illustrate three-dimensional views of electronic components 100 with semiconductor body 102. FIG. 16 corresponds to the chamfer value of FIG. 8, FIG. 17 corresponds to the chamfer value of FIG. 9, FIG. 18 corresponds to the chamfer value of FIG. 10, and FIG. 19 corresponds to the chamfer value of FIG. 11. The findings described referring to FIG. 7 to FIG. 11 are confirmed by the findings according to FIG. 16 to FIG. 19.

FIG. 20 to FIG. 23 shows simulation results of von-Mises stress at a leadframe and illustrate three-dimensional views of electronic components 100 on a corresponding carrier 122. FIG. 20 corresponds to FIG. 16, FIG. 21 corresponds to FIG. 17, FIG. 22 corresponds to FIG. 18, and FIG. 23 corresponds to FIG. 19. The findings described referring to FIG. 7 to FIG. 11 are confirmed by the findings according to FIG. 20 to FIG. 23.

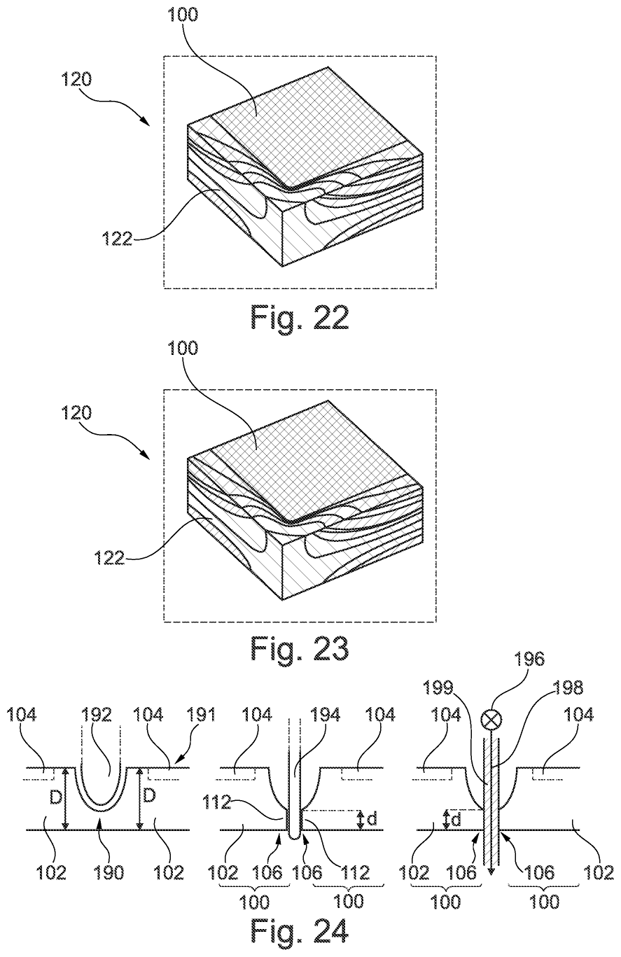

FIG. 24 illustrates cross-sectional views during executing a method of manufacturing an electronic component 100 according to an exemplary embodiment. More specifically, FIG. 24 illustrates different scenarios of forming a stress release structure 106 as a lateral edge portion 112 of a semiconductor body 102 by dicing. In other words, dicing and formation of a stress release structure 106 may be synergistically combined, which may lead to an efficient manufacturing process of a plurality of electronic components 100 from a semiconductor wafer 191. FIG. 24 illustrates processes of separating semiconductor bodies 102 from wafer 191 along separation lines 190 so that the stress release structures 106 are formed as a side product during said separating.

The left-hand side of FIG. 24 shows that said separating comprises carrying out a first separation process penetrating only along a partial thickness into the wafer 191 along said separation lines 190 (for instance a dicing street). The first separation process is executed by mechanically dicing using a dicing blade 192 with broad cutting profile.

The central image and the right-hand side of FIG. 22 show two options for carrying out a subsequent second separation process penetrating completely through the wafer 191 after the process illustrated on the left-hand side.

The central image shows an embodiment in which also the second separation process comprises a mechanical dicing process. More specifically, the second separation process is executed by mechanically dicing using another dicing blade 194 with a narrower cutting profile than dicing blade 192. As a result, a chamfer profile is obtained at a lateral edge portion 112 of each of the separated semiconductor bodies 102 by the combination of two dicing blades 192, 194 with different cutting profiles. Thus, the geometry of the lateral edge portion 112 may be defined by the geometrical shape of the dicing blades 192, 194.

Now referring to the right-hand side of FIG. 24, the second separation process may comprise alternatively a laser dicing process. In the shown embodiment, said laser dicing process is executed by a liquid-guided laser. More specifically, a laser source 196 emits a laser beam 198 which propagates inside of a liquid body 199 during cutting entirely through wafer 191. Such a wet laser cutting process may allow a precise guidance and cooling of the laser beam 198 and may reduce burn-off of the wafer 191. By adjusting the properties of the laser cutting process in combination with the adjustment of the properties of the mechanical dicing process according to the left-hand side of FIG. 24, the shape of the lateral edge portions 112 may be defined.

Although not shown, it is also possible to form the stress release structures 106 by etching the wafer 191 or the already separated electronic components 100.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An electronic component, comprising:
a semiconductor body;
an active region in a central portion of the semiconductor body; and
a stress release structure for releasing stress and being formed as a lateral edge portion of the semiconductor body, said lateral edge portion having a minimum thickness of not more than 40% of a maximum thickness of the semiconductor body.

2. The electronic component according to claim 1, wherein a lateral extension of the stress release structure between an exterior edge of the semiconductor body and a position at which the semiconductor body reaches its maximum thickness is at least 10% of the maximum thickness of the semiconductor body.

3. The electronic component according to claim 2, wherein said lateral extension of the stress release structure is at least 20% of the maximum thickness of the semiconductor body.

4. The electronic component according to claim 2, wherein said lateral extension of the stress release structure is not more than 150 μm.

5. The electronic component according to claim 1, wherein said lateral edge portion has a minimum thickness of not more than 20% of the maximum thickness of the semiconductor body.

6. The electronic component according to claim 1, wherein said lateral edge portion has a minimum thickness of zero at an exterior edge of the semiconductor body.

7. The electronic component according to claim 1, wherein at least part of the lateral edge portion has a concave shape or has a straight shape.

8. The electronic component according to claim 1, wherein the maximum thickness is in a range from 20 μm to 220 μm.

9. The electronic component according to claim 1, wherein the minimum thickness at the lateral edge portion is not more than 50 μm.

10. The electronic component according to claim 1, comprising at least one of the following features:
wherein the stress release structure extends along an entire circumference of the semiconductor body;
wherein the stress release structure is delimited by a vertical section at an exterior edge of the semiconductor body and by a slanted section connected between said vertical section and a horizontal surface of the semiconductor body, wherein in particular the slanted section is straight or concave;
wherein the stress release structure is configured for releasing tensile stress;
configured as a power semiconductor chip;
wherein the semiconductor body comprises silicon carbide; and
wherein the stress release structure is formed as a stress release notch or as a stress release chamfer at the lateral edge portion of the semiconductor body.

11. A package, comprising:
a carrier; and
an electronic component according to claim 1 and being mounted on the carrier;
wherein the stress release structure of the electronic component releases stress at an interface between the lateral edge portion and the carrier.

12. The package according to claim 11, comprising at least one of the following features:
wherein the carrier comprises a metallic material at the interface with the electronic component;
wherein the carrier comprises one of the group consisting of a leadframe structure, and a ceramic sheet with metallic layers on both opposing main surfaces thereof;
comprising a solder layer between the carrier and the electronic component, wherein in particular the solder layer has a thickness of less than 10 μm, in particular a thickness in a range from 1 μm to 5 μm.

13. A method of manufacturing an electronic component, wherein the method comprises:
forming an active region in a central portion of a semiconductor body; and
forming a stress release structure for releasing stress as a lateral edge portion of the semiconductor body, said lateral edge portion being formed with a minimum thickness of not more than 40% of a maximum thickness of the semiconductor body.

14. The method according to claim 13, wherein the method comprises separating the semiconductor body from a wafer along separation lines so that the stress release structure is formed by said separating.

15. The method according to claim 14, wherein said separating comprises carrying out a first separation process penetrating into the wafer, and carrying out a subsequent second separation process penetrating through the wafer.

16. The method according to claim 15, wherein one or both of the first separation process and the second separation process comprises a mechanical dicing process.

17. The method according to claim 15, wherein the second separation process comprises a laser dicing process.

18. The method according to claim 14, wherein said separating comprises carrying out a single separation process penetrating through the wafer by a laser, in particular by a multi-beam laser or by a liquid-guided laser.

19. The method according to claim 13, wherein the method comprises forming the stress release structure by etching.

20. The method according to claim 13, wherein the method comprises mounting the electronic component on a carrier by soldering.
